(19) United States
(12) Patent Application Publication
(10) Pub. No.: US 2003/0007393 A1
(43) Pub. Date: Jan. 9, 2003

(54) Method and apparatus for testing memory arrays

(75) Inventors: Steven Michael Eustis, Essex Junction, VT (US); Robert Lloyd Barry, Essex Junction, VT (US); Peter Francis Croce, Essex Junction, VT (US)

Correspondence Address: Richard A. Henkler, IP Law Department, 972E, IBM Corporation, 1000 River Street, Essex Junction, VT, 05452, US

(73) Assignee: International Business Machines Corporation, Armonk, NY

(21) Appl. No.: 09/885,570

(22) Filed: Jun. 20, 2001

(51) Int. Cl. G11C 7/00

(52) U.S. Cl. 365/200

(57) ABSTRACT

A method and apparatus for testing memory arrays where the addresses associated with such arrays exceeds the physical boundaries of the array. Addresses that are outside the physical boundary of the array are considered invalid addresses; while those residing within the physical boundaries are considered valid addresses. The method and apparatus tests the memory array by only loading data into the data out latch of the memory array when a valid address is received.

### BACKGROUND OF THE INVENTION

1. Technical Field

The present invention generally relates to memory arrays and the devices that incorporate such arrays, and more specifically to methods and apparatuses that test the memory arrays.

2. Description of the Related Art

Computer memory components, e.g., random access memory (RAM) and read-only memory (ROM), are designed with arrays to hold data. These arrays are typically subdivided into cells with each cell being associated with a unique address. Address lines are used to access the unique addresses where the number of address lines is directly related to number of addressable cells. In example, an eight-cell array would require three address lines for the combination of eight unique addresses.

In certain situations (e.g., ASIC designs), the number of unique addresses that can be asserted on the address line will exceed the physical boundaries of the memory array (i.e. more address space than memory space). These types of situations become a concern during the testing of the memory component.

The memory component is subjected to a series of logic tests to ensure that data is being read correctly. The testing of the memory component is typically conducted by testing the results of randomly generated addresses to ensure that valid data is read. If the generated address is outside the physical boundaries of the memory array, then the memory array must still provide valid data. Various techniques for providing the valid data during such a generated address have been developed, but fail to overcome the issues associated with glitches, skew, or performance.

It would, therefore, be a distinct advantage to have a method and apparatus that could test memory arrays that are addressable outside their physical boundaries while providing valid data for such addresses. The present invention provides such a method and apparatus.

### SUMMARY OF THE INVENTION

The present invention tests memory arrays where the addresses associated with such arrays exceeds the physical boundaries of the array. Addresses that are outside the physical boundary of the array are considered invalid addresses, while those residing within the physical boundaries, are considered valid addresses. The present invention tests the memory array by only loading data into the data out latch of the memory array when a valid address is received. During the reception of an invalid address the data out latch is not loaded. The testing of the memory component involves the assertion of a valid address, the reading of the data from the data out latch, the assertion of an invalid address, and the reading of the data from the data out latch.

In the preferred embodiment of the present invention, the valid data is always a complement of the address for the invalid data. In other words, at least 50 percent of the addressable portions of the array must reside within the physical boundaries of the array.

### BRIEF DESCRIPTION OF THE DRAWINGS

FIG. 1 is a schematic diagram illustrating an example of addressing circuitry of a memory component 200 that can be used in conjunction with a preferred embodiment of the present invention;

### DETAILED DESCRIPTION OF AN ILLUSTRATIVE EMBODIMENT

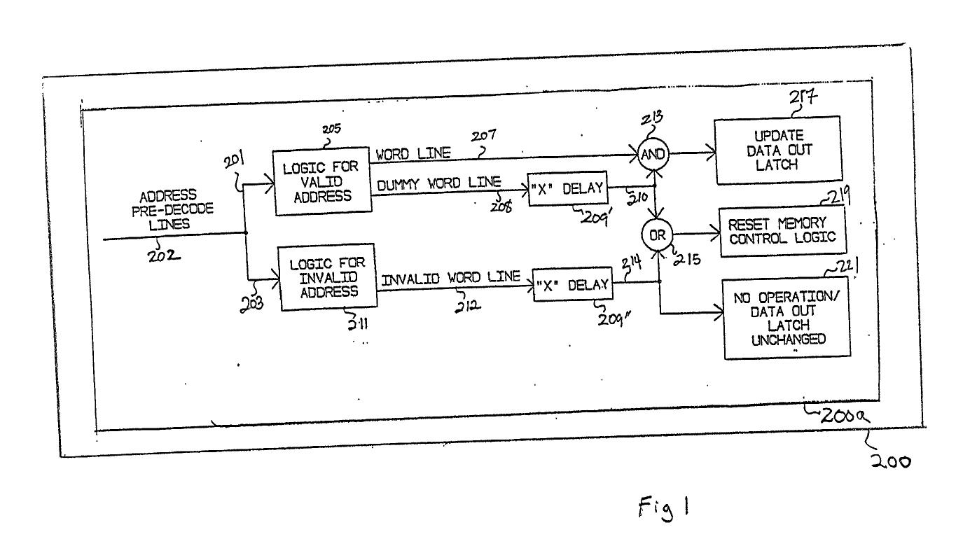

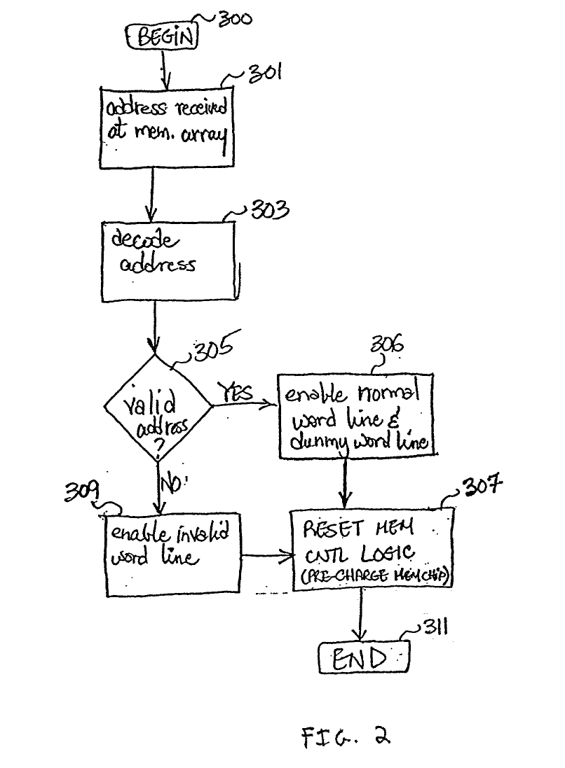

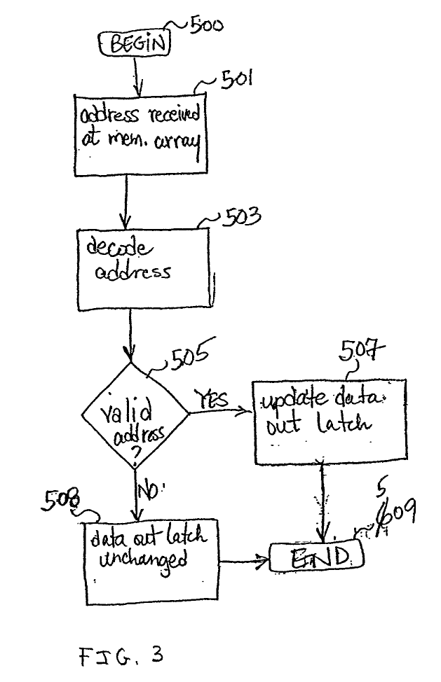

FIG. 1 is a schematic diagram illustrating an example of a memory component 200 that can be used in conjunction with a preferred embodiment of the present invention. The memory component 200 includes addressing circuitry 200a for decoding received addresses. As previously discussed, an address can reside within or outside the physical boundaries of the memory component 200. Regardless of where the address resides, the memory component 200 must provide valid data upon the receipt of an address. The memory component 200 provides this valid data by receiving an address on address pre-decode lines 202, and feeding the received address to both the logic for valid address 205 and logic for invalid address 211. As the names imply, the logic for valid address 205 is used for addresses residing within the physical boundaries of the memory component 200, while the logic for invalid address 211 is used for addresses residing outside the physical boundaries of the memory component.

The logic for valid address 205 has two output lines, word line 207 and dummy word line 208, each selected based on the output from valid address logic 205. Dummy word line 208 is coupled to first “X” delay logic 209′, which delays the signal from dummy word line 208.

The logic for invalid address 211 has a single output line, invalid word line 212, which is coupled to a second “X” delay logic 209″ which delays the signal from the invalid word line 212.

The signals/data present on word line 207 and delayed dummy word line 210 are ANDed together via AND logic 213, and the output from the AND logic 213 (i.e., the result of the ANDing operation) is coupled to data out latch 217. The result of the ANDing operation triggers an update of data out latch 217.

The delayed dummy word line 210 and delayed invalid word line 214 are ORed via OR logic 215. The output of OR logic 215 is coupled to memory control logic 219. The result of the ORing operation provides a trigger to reset memory control logic 219. The delayed invalid word line 214 is also coupled to logic 221 that controls the data out latch 217 and causes the data out latch 217 to remain unchanged.

Accordingly, in operation, when an invalid address is received (or detected), the addressing circuitry 200a decodes the invalid address using logic for invalid address 211 and fires an “invalid word line” 212. The normal array (i.e., word line 207) does not fire, and the invalid word line 212 leads to circuitry to reset the control logic 219 in preparation for the next data access. Also, the data output latches do not change from the prior address access, and thus, the memory component 200 provides a predictable result.

One advantage of the present invention is that it requires few logic or signal additions. The memory design is able to use existing performance driven pre-decode address lines. A few logic gates may be added to the dummy word line circuitry to create the detection and drive of the invalid word line. Thus, no new circuitry is needed.

Another feature of the present invention is that similar timing paths are generated for the valid and invalid addresses via the dummy word line 208 and invalid word line 212. This feature of the operation of memory component 200 allows reduced setup times because an incorrect decode “glitch” of an invalid address will process in parallel with the correct valid decode. The dummy word line 208 and invalid word line 212 will reset the circuitry at the same time allowing for the proper data in the data out latches.

The present invention's similar timing is achieved by running the invalid word line parallel to the dummy word line around the perimeter of the array. As the array grows and shrinks for each chip, the invalid word line will also grow and shrink with the dummy word line. A glitch on the invalid word line will, therefore, not end the current cycle before the proper data is stored in the data out latches. Also, because of the timing similarity, if an invalid address is decoded as the address lines are changing, the invalid address does not have a chance to “cut off” a valid address memory access once the address lines stabilize.

FIG. 2 is a flow chart illustrating the operation of the memory component 200 of FIG. 1 according to the teachings of a preferred embodiment of the present invention. The process begins at block 300 and proceeds when an address is received as shown at block 301. Once received, the address is decoded as illustrated at block 303. After (or while) the address is decoded, the memory decode logic decides at block 305 whether the address is valid or invalid. If the address is valid, then the normal word line and dummy word line path are enabled at block 306. The data out latch is updated and the memory chip pre-charges, and the memory control logic is reset at the end of the cycle as depicted at block 307. The operation then ends at block 311.

The present invention tests invalid addresses in memory components that do not update their data out latch when an invalid address is read. For example, the memory component 200 does not update the update data out latch 217 when an invalid address is read, but only when a valid address is read. Memory designers recognize that memory components, such as memory component 200, need to be tested exhaustively for stuck-at faults and other such potential memory defects.

FIG. 3 is a flow chart illustrating the method used by a preferred embodiment of the present invention for testing memory components. In general, the present invention tests the memory component by alternating the testing of valid and invalid addresses. More specifically, the present invention tests a valid address by first accessing the complement of the target address, and then accessing the target address thereafter. The methodology is based upon the premises that the complement of the target address will always be a valid address, and that the data latch of the memory component is not updated on an invalid address request. Thus, each invalid address is tested one at a time with a different valid address read in between.

An example of a non power of two ROM code is illustrated below. The example utilizes 3 address bits, which have 6 valid addresses (0-5) and 2 invalid addresses (6-7).

| | | | | |
|---|---|---|---|---|
| C | 000 | | 000 | |
| T | 111 | 7 | 000 | 0 |
| C | 001 | | 001 | |
| T | 110 | 6 | 001 | 1 |
| C | 010 | | | |
| T | 101 | 5 | 101 | 5 |
| C | 011 | | | |
| T | 100 | 4 | 100 | 4 |
| C | 100 | | | |
| T | 011 | 3 | 011 | 3 |
| C | 101 | | | |
| T | 010 | 2 | 010 | 2 |
| C | 110 | | | |
| T | 001 | 1 | 001 | 1 |
| C | 111 | | | |
| T | 000 | 0 | 000 | 0 |

The first column shows the complement/target address scheme. The target address starts at the highest address and counts down, while the complement address begins at the lowest address and counts up. The second column shows which address data is ultimately loaded into the Serial Input Shift Register (SISR). SISR's are well known and understood by those skilled in the relevant art, and are described in detail in “Build in self test for VLSI: PsedoRandom Techniques”, published by John Wiley & Sons, Inc. 1987. In the preferred embodiment, even though an invalid address is tested, the SISR always obtains data from a valid address and the address accessed is different each cycle. The data is also provided in an easy pattern in ascending order for the invalid addresses and descending order for the valid addresses.

Returning now to FIG. 3, the process begins at block 500 and proceeds when an address is received as shown at block 501. Once received, the address is decoded as illustrated at block 503. After (or while) the address is decoded, the memory decode logic decides at block 505 whether the address is valid or invalid. If the address is valid, then the data out latches are updated properly as shown at block 507. Then the read process ends as illustrated at block 509. If, however, the address is an invalid address, the data out latches remain unchanged as shown at block 508, and then the read process ends at block 509.

Thus, each read to the memory array consists of two reads. The first read is to the complement of the target address, and the second read is performed on the target address. The result of the second read is read into a SISR In a memory array with “N” invalid addresses, if the maximum power of two addresses are decremented from the point of the first read, the stream of data going into the SISR will appear as if the first “N” valid addresses were read in ascending order from the lowest address (0) followed by all of the valid addresses in descending order from the highest valid address. Thus, the testing process allows any multiple number of reads to be completed so long as the final two reads are to a complement (C) and then a target (T) address. For example, a four read process may be CCCT, CTCT, TCCT, or TTCT, in which the last two reads loaded into the SISR is always CT.

Advantages recognized from the invention include (1) each invalid address is tested one at a time, interspersed by valid addresses such that the output of the array is not a “sea of unchanged data”, and (2) no silicon updates are needed to the existing ROM BIST structure (i.e., only the scan initialization vector and SISR signature change).

It is important to note that while the present invention has been described in the context of a fully functional data processing system, those skilled in the art will appreciate that the mechanism of the present invention is capable of being distributed in the form of a computer readable medium of instructions in a variety of forms, and that the present invention applies equally, regardless of the particular type of signal bearing media utilized to actually carry out the distribution. Examples of computer readable media include: nonvolatile, hard-coded type media such as Read Only Memories (ROMs) or Erasable, Electrically Programmable Read Only Memories (EEPROMs), recordable type media such as floppy disks, hard disk drives and CD-ROMs, and transmission type media such as digital and analog communication links.

It is thus believed that the operation and construction of the present invention will be apparent from the foregoing description. While the method and system shown and described has been characterized as being preferred, it will be readily apparent that various changes and/or modifications could be made wherein without departing from the spirit and scope of the present invention as defined in the following claims.

What is claimed is:

1. A method of testing invalid addresses of a memory component having a data out latch for storing data associated with a particular address location, the method comprising the steps of:
loading, in response to receiving a valid address, the data associated with the valid address into the data out latch;
asserting an invalid address to the memory component; and
reading the data associated with the valid address from the data out latch.

2. The method of claim 2 wherein the valid addresses reside within the physical dimensions of the memory component.

3. The method of claim 2 wherein the invalid addresses reside outside the physical dimensions of the memory component.

4. The method of claim 3 wherein valid addresses are complements of invalid addresses.

5. A method of testing a memory component having a data out latch for storing data associated with a particular address, the method comprising the steps of:
loading data into the data latch only upon the receipt of a valid address.

6. The method of claim 5 wherein a valid address resides within the physical dimensions of the memory component.

7. The method of claim 6 wherein an invalid address resides outside the physical dimensions of the memory component.

8. The method of claim 7 further comprising the steps of:
asserting a valid address to the memory component;
asserting an invalid address to the memory component; and
reading the data associated with the valid address from the memory component.

9. An apparatus for testing invalid addresses of a memory component having a data out latch for storing data associated with a particular address location, the apparatus comprising:
means for loading, in response to receiving a valid address, the data associated with the valid address into the data out latch;
means for asserting an invalid address to the memory component; and
means for reading the data associated with the valid address from the data out latch.

10. The apparatus of claim 9 wherein the valid addresses reside within the physical dimensions of the memory component.

11. The apparatus of claim 10 wherein the invalid addresses reside outside the physical dimensions of the memory component.
